(19) United States
(12) Patent Application Publication
(10) Pub. No.: US 2005/0098201 A1
(43) Pub. Date: May 12, 2005

(54) Pure metal thermocouple and a normal temperature compensating wire therefor

(76) Inventors: Yong Gyoo Kim, Daejeon-si (KR); Kee Hoon Kang, Daejeon-si (KR); Kee Sool Gam, Gongju-si (KR)

Correspondence Address: Thomas R. FitzGerald, Esq.;Suite 210, 16 E. Main Street, Rochester, NY, 14614-1803, US

(21) Appl. No.: 10/927,369

(22) Filed: Aug. 26, 2004

(30) Foreign Application Priority Data
Nov. 7, 2003 (KR) 10-2003-0078591

(51) Int. Cl. H01L 35/28

(52) U.S. Cl. 136/224

(57) ABSTRACT

Disclosed are a high purity metal thermocouple and a normal temperature compensating wire for the high purity metal thermocouple. The high purity metal thermocouple comprises a first high purity metal wire having a certain length, and a second high purity metal wire disposed at the proximity of the first high purity metal wire in parallel therewith. One end of the second high purity metal wire is contacted with one end of the first high purity metal wire so as to have an electrical correlationship based on a heat variation. Each of first and second compensating wires has a certain length and is connected respectively to the first and second high purity metal wires. The first and second high purity metal wires are formed respectively of platinum and palladium. The first compensating wire is formed of 95˜95.5 wt % copper and 4.5˜5 wt % nickel. The second compensating wire is formed of 89.5˜90 wt % copper and 10˜10.5 wt % nickel.

### BACKGROUND OF THE INVENTION

1. Field of the Invention

The present invention relates to a high purity metal (so-called “pure metal”) thermocouple and a normal temperature compensating wire therefor, in which the thermocouple wire is formed of pure metals and the compensating wire is formed of a Cu—Ni alloy, and which is universally applied to a variety of industries.

2. Background of the Related Art

In general, a thermocouple can be described by a temperature measuring tool, in which two dissimilar metal conductors bonded together generates an electromotive force by the Seeback effect, in response to a temperature of the bonded area, and the electromotive force varies with the temperature, thereby detecting the temperature value using the electromotive force. Particularly, in case of a high temperature, the thermocouple generates a high voltage, which can be converted into a corresponding temperature value by means of an instrument. This voltage is called a “heat electromotive force.”

The thermocouple has a fast responsive characteristic, a relatively narrow error range with respect to a delayed time, and a wide range of measurable temperature. Further, by using a heat electromotive force, information processing such as the measurement, adjustment, control, conversion or the like can be readily carried out, thereby allowing for a universal use in the industries.

Conventionally, a typical thermocouple is a S-type one, which is composed of platinum and rhodium alloy. The S-type thermocouple has a disadvantage in that a change in its composition occurs due to evaporation of rhodium while a long-time use, and therefore its performance is deteriorated over time.

Many research has been conducted in the industrial and academic areas in order to overcome these problems and develop a pure metal thermocouple such as a gold/platinum, a platinum/palladium, a gold/palladium or the like.

Among them, the platinum/palladium thermocouple has a thermoelectric characteristic capable of detecting up to about 1400° C., and thus is known as a precision temperature sensor in a high temperature range. Therefore, a concentrated research has been carried out on the Pt/Pd thermocouple system.

However, in spite of the above characteristics, the research on the Pt/Pd thermocouple has been conducted mainly in a laboratory scale in the academic domain. Also, the use of the Pt/Pd thermocouple is limited to a lab-scale. Accordingly, there is a need to provide a pure metal thermocouple, which can be readily applied to the whole industries, and can be easily and conveniently used.

### SUMMARY OF THE INVENTION

Therefore, the present invention has been made in order to solve the above problems occurring in the prior art, and it is an object of the present invention to provide a pure metal thermocouple and a compensating wire for the pure metal thermocouple, which can be universally used in a variety of industries.

A further object of the invention is to provide a pure metal thermocouple and a compensating wire for the pure metal thermocouple, in which the compensation wire can be extended enough to measure a high temperature in a safety distance.

In order to accomplish the above objects, according to one aspect of the invention, there is provided a pure metal thermocouple. The pure metal thermocouple includes: a first pure metal wire having a certain length; a second pure metal wire disposed at the proximity of the first pure metal wire in parallel therewith, one end of the second pure metal wire being contacted with one end of the first pure metal wire so as to have an electrical correlationship based on a heat variation; and first and second compensating wires each having a certain length and being connected respectively to the first and second pure metal wires.

The respective first and second compensating wire is connected respectively to the first and second pure metal wire having electrically the same polarity.

The first pure metal wire has a positive (+) polarity and is formed of platinum, and the second pure metal wire has a negative (−) polarity and is formed of palladium.

Alternatively, the first pure metal wire may be formed of gold, and the second pure metal wire may be formed of platinum. Or the first pure metal wire may be formed of gold, and the second pure metal wire may be formed of palladium.

According to the invention, the first compensating wire is formed of 95˜95.5 wt % copper and 4.5˜5 wt % nickel, and the second compensating wire is formed of 89.5˜90 wt % copper and 10˜10.5 wt % nickel.

Preferably, an insulator can be further provided for sheathing the first and second pure metal wires. The insulator may be formed of a ceramic material such as alumina.

According to another aspect of the invention, there is provided a thermocouple compensating wire for a pure metal thermocouple. The thermocouple compensating wire of the invention includes: a first compensating wire being connected to a first pure metal thermocouple wire, the first compensating wire having electrically the same polarity as the first pure metal thermocouple wire; and a second compensating wire being connected to a second pure metal thermocouple wire, the second compensating wire having electrically the same polarity as the second pure metal thermocouple wire, the second pure metal thermocouple wire being disposed at the proximity of the first pure metal thermocouple wire in parallel therewith, one end of the second pure metal thermocouple wire being contacted with one end of the first pure metal thermocouple wire so as to have an electrical correlationship based on a heat variation; wherein the first compensating wire is formed of 95˜95.5 wt % copper and 4.5˜5 wt % nickel, and the second compensating wire is formed of 89.5˜90 wt % copper and 10˜10.5 wt % nickel.

The first pure metal thermocouple wire has a positive (+) polarity and is formed of platinum, and the second pure metal thermocouple wire has a negative (−) polarity and is formed of palladium.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 illustrates a general configuration of a pure metal thermocouple according to one embodiment of the invention; and

FIG. 2 is a diagram showing the variation in a heat electromotive force of the compensating wires and pure metal wires according to the invention.

### DETAILED DESCRIPTION OF THE PREFERRED EMBODIMENT

Reference will now made in detail to the preferred embodiment of the present invention with reference to the attached drawings.

Referring to the accompanying drawings, the preferred embodiments according to the present invention are hereafter described in detail.

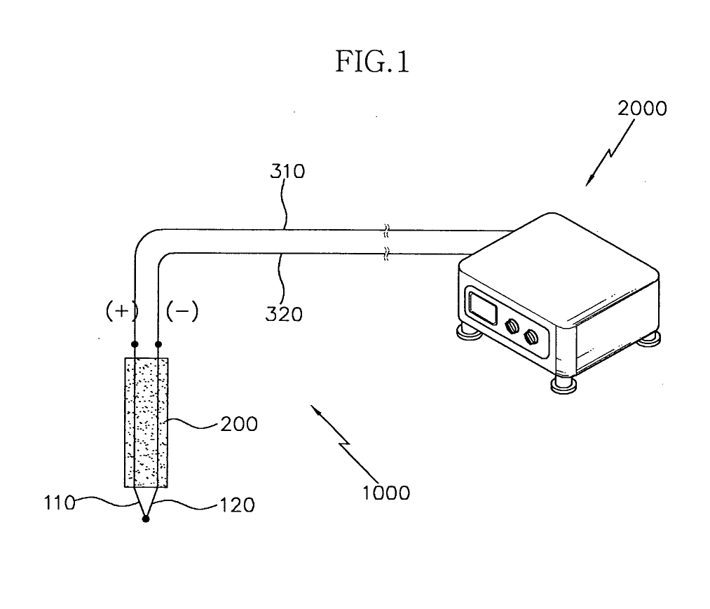

FIG. 1 illustrates a general configuration of a pure metal thermocouple according to one embodiment of the invention, in which the pure metal thermocouple is generally denoted at 1000. As shown in FIG. 1, the pure metal thermocouple 1000 is composed of a first pure metal thermocouple wire 110 and a second pure metal thermocouple wire 120, which generates a heat electromotive force by the Seeback effect, in response to a temperature difference. One ends of two pure metal thermocouple wires 110, 120 are connected with each other, for example, welded to each other. The other ends of the two pure metal thermocouple wires are connected respectively to a normal temperature compensating wire. According to the invention, the normal temperature compensating wire is formed of a nickel-copper alloy.

In the description, the terms “pure metal thermocouple wire” and “normal temperature compensating wire” are referred to simply as a “pure metal wire” and “compensating wire” respectively.

With the above compensation configuration and the compensating wire formed of a copper-nickel alloy, a normal temperature compensation can be achieved with a range of about ±1° C. error such that it can be widely used in a variety of industries. Due to such normal temperature compensation configuration according to the invention, the heat electromotive force in an actual temperature measurement is transmitted to an external instrumental system with no significant loss through the compensating wire, thereby enabling a relatively accurate measurement of temperature, along with the convenience of use.

In the compensation configuration according to the invention, the first pure metal wire 110 has a positive polarity and is formed of platinum, and the second pure metal wire 120 has a negative polarity and is formed of palladium. The second compensating wire 310 connected to the first pure metal 110 is formed of a Cu—Ni alloy consisting of about 95˜95.5 wt % copper and about 4.5˜5 wt % nickel, and the second compensating wire 320 connected to the second pure metal wire 120 is formed of a Cu—Ni alloy consisting of about 89.5˜90 wt % copper and about 10˜10.5 wt % nickel.

The thermocouple 1000 of the invention comprises a first pure metal wire 110 and a second pure metal wire 120, and a first compensating wire 310 and a second compensating wire 320 connected to the first and second pure metal wires respectively and having the same polarities as the pure metal wires. The first and second pure metal wires 110, 120 are sheathed with an insulator 200.

The insulator 200 is formed of ceramic materials such as alumina having a good dielectric property, and the pure metal wires 110, 120 are neighbored to each other such that they have an electrical correlationship, based on the heat variation.

The pure metal wires 110, 120 are disposed near to each other and one ends thereof are bonded with each other such that they generates an electromotive force due to a heat variation, i.e., a temperature change. These two dissimilar pure metals has a conductivity, and is configured such that a heat electromotive force is generated in response to a thermal variation, and this electromotive force can be derived into a temperature change through a certain circuit. I.e. the electromotive force is transmitted to a digital instrument 2000, to which the pure metal wires 110, 120 are connected. The digital instrument 2000 determines a temperature value based on the transmitted electromotive force.

The first pure metal wire 110 has a positive (+) polarity and is formed of platinum, and the second pure metal wire 120 has a negative (−) polarity and is formed of palladium. The two pure metal wires are disposed in parallel and the end portions of them are contacted with each other, and a heat electromotive force is generated due to the heat at the contact point.

The other ends of the pure metal wires 110, 120 is electrically connected to the compensating wires, which is formed of a Cu—Ni alloy according to the invention. In other words, the first pure metal wire 110 is connected to the first compensating wire 310, and the second pure metal wire 120 is connected to the second compensating wire 320.

The first compensating wire 310 is formed of a Cu—Ni alloy consisting of about 95˜95.5 wt % copper and about 4.5˜5 wt % nickel, and the second compensating wire 320 is formed of a Cu—Ni alloy consisting of about 89.5˜90 wt % copper and about 10˜10.5 wt % nickel.

With the above construction, an electromotive force generated from the pure metal wires 110, 120 is transmitted to an external instrument through the compensating wires 310, 320. When an actual temperature measurement is carried out, the other ends of the compensating wires 310, 320 are connected with an electromotive force measuring system such as the digital instrument 2000 in FIG. 1, and the respective compensating wire is immersed into an ice water of 0° C., thereby enabling a temperature of the contact point of the pure metal wires to be measured, relatively to the 0° C. of the ice water.

It is known that the Pt/Pd thermocouple system has an error range of about ±0.01° C. The compensating wires of the invention has an error range of about ±1° C., and therefore can be extensively applied to a variety of industries, when contrasted with the error range of the Pt/Pd thermocouple system.

In addition, the compensating wires 310, 320 can extend the pure metal wires 110, 120 to the digital instrument 2000. Therefore, a long compensating wire can be used when a high-temperature object is measured, so that the high-temperature change can be safely measured at a distance.

Furthermore, as described above, the error range of the first and second pure metal wires 110, 120 is not largely deviated from that of the compensating wires 310, 320, so that the heat electromotive force generated from the Pt/Pd couple can be effectively transmitted to the digital instrument 2000 with no greater loss, thereby enabling a relatively accurate measurement, along with a convenient of use.

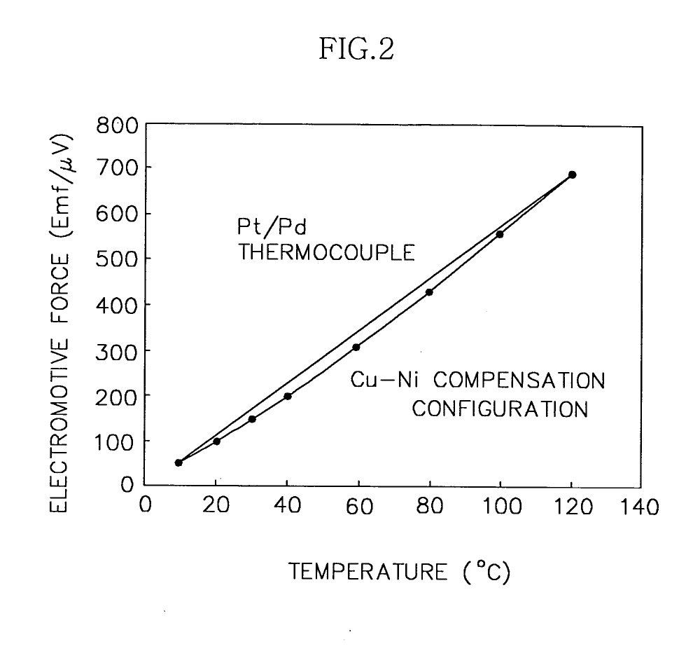

FIG. 2 is a diagram showing the variation in a heat electromotive force of the compensation wires and pure metal wires according to the invention. As shown in FIG. 2, the thermocouple 1000 of the invention is composed of a first pure metal wire 110 formed of platinum and a second pure metal wire 120 formed of palladium.

In addition, the first compensating wire 310 is formed of an alloy consisting about 95 wt % copper and about 5 wt % nickel, and the second compensating wire 320 is formed of an alloy consisting about 90 wt % copper and about 10 wt % nickel. Thereafter, the electromotive force is measured and compared with respect to the Pt/Pd thermocouple and the compensating wires of the invention.

In FIG. 2, the X-axis denotes a temperature (° C.), and Y-axis denoted a heat electromotive force (Emf/μV). In addition, the solid line in FIG. 2 corresponds to the Pt/Pd thermocouple without the compensating wires of the invention, and the other line having black dots marked thereon corresponds to the compensation configuration using the compensating wires 310, 320 formed of a Cu—Ni alloy according to the invention.

As shown in FIG. 1, it has been found that the difference in the electromotive forces is trivial although a slight deviation occurs shown in the range of between around 20˜110° C. Therefore, the compensating wires, which are formed respectively of 95 wt % Cu-5wt % Ni and 90 wt % Cu-10 wt % Ni, can be used for a temperature measurement in various industries, with a reasonable and applicable error range.

As described above, in this embodiment, a platinum/palladium thermocouple is illustrated, but not limited thereto. For example, other types of pure metal thermocouple wires such as a gold/platinum, a platinum/palladium, and a gold/palladium series may be used, together with the compensating wires according to the invention.

Furthermore, a supplemental sheath structure for protecting the respective compensating wire can be used, along with the compensating wires formed of a copper-nickel alloy, within the scope of the present invention.

As described above, the pure metal thermocouple wires and compensating wires therefor of the invention have a small difference in their electromotive forces, relative to the Pt/Pd thermocouple system, to the extent that they can be widely used in the industries.

Furthermore, an extended compensating wire can be used for measuring a temperature at a distance, thereby enabling a safety of temperature measurement within the range of temperature that a Pt/Pd thermocouple can be applied to.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

Those skilled in the art understand that the term “pure metal” means a metal of such high purity that it behaves for its intended purpose as though it consisted of only one metal and no other substance. Modem manufacturing techniques enable those skilled in the art to make gold, platinum, palladium and other metals that are more than 99% pure and are up to 99.999% pure. This patent includes such purities in its disclosure and the metals used in the thermocouples are of such high purity that they perform in thermocouples in a manner substantially similar to metals of 100% purity. Accordingly, as used in the patent, the term “pure metal” means a metal that consists essentially of the metal. Of course, if it becomes possible to manufacture 100% pure metals, this patent also covers thermocouples with such 100% pure metals.

1. A high purity metal thermocouple comprising:
a first high purity metal wire consisting essentially of a first metal and having a certain length;
a second high purity metal wire consisting essentially of a second metal disposed at the proximity of the first high purity metal wire in parallel therewith, one end of the second high purity metal wire being contacted with one end of the first high purity metal wire so as to have an electrical correlationship based on a heat variation; and
first and second compensating wires each having a certain length and being connected respectively to the first and second high purity metal wires.

2. A high purity metal thermocouple according to claim 1, wherein the first high purity metal wire has a positive (+) polarity and is formed of platinum, and the second high purity metal wire has a negative (−) polarity and is formed of palladium.

3. A high purity metal thermocouple according to claim 1, wherein the first high purity metal wire has a positive (+) polarity and is formed of gold, and the second high purity metal wire has a negative (−) polarity and is formed of platinum.

4. A high purity metal thermocouple according to claim 1, wherein the first high purity metal wire has a positive (+) polarity and is formed of gold, and the second high purity metal wire has a negative (−) polarity and is formed of palladium.

5. A high purity metal thermocouple according to claim 1, wherein the respective first and second compensating wire is connected respectively to the first and second high purity metal wire having electrically the same polarity.

6. A high purity metal thermocouple according to claim 1, wherein the first compensating wire is formed of 95˜95.5 wt % copper and 4.5˜5 wt % nickel.

7. A high purity metal thermocouple according to claim 1, wherein the second compensating wire is formed of 89.5˜90 wt % copper and 10˜10.5 wt % nickel.

8. A high purity metal thermocouple according claim 1, wherein an insulator is further provided for sheathing the first and second high purity metal wires.

9. A high purity metal thermocouple according to claim 8, wherein the insulator is formed of alumina.

10. A high purity metal thermocouple according to claim 8, wherein the insulator is formed of a ceramic material.

11. A normal temperature compensating wire for a high purity metal thermocouple comprising:
a first compensating wire being connected to a first high purity metal thermocouple wire, the first compensating wire having electrically the same polarity as the first high purity metal thermocouple wire; and
a second compensating wire being connected to a second high purity metal thermocouple wire, the second compensating wire having electrically the same polarity as the second high purity metal thermocouple wire, the second high purity metal thermocouple wire being disposed at the proximity of the first high purity metal thermocouple wire in parallel therewith, one end of the second high purity metal thermocouple wire being contacted with one end of the first high purity metal thermocouple wire so as to have an electrical correlationship based on a heat variation;
wherein the first compensating wire is formed of 95˜95.5 wt % copper and 4.5˜5 wt % nickel, and the second compensating wire is formed of 89.5˜90 wt % copper and 10˜10.5 wt % nickel.

12. A normal temperature compensating wire according to claim 11, wherein the first high purity metal thermocouple wire has a positive (+) polarity and is formed of platinum, and the second high purity metal thermocouple wire has a negative (−) polarity and is formed of palladium.
